(19) United States
(12) Patent Application Publication
(10) Pub. No.: US 2020/0089064 A1
(43) Pub. Date: Mar. 19, 2020

(54) DISPLAY DEVICE

(71) Applicant: Sharp Kabushiki Kaisha, Sakai City (JP)

(72) Inventors: Junichi MORINAGA, Sakai City (JP); Hikaru YOSHINO, Sakai City (JP)

(21) Appl. No.: 16/571,329

(22) Filed: Sep. 16, 2019

Related U.S. Application Data
(60) Provisional application No. 62/733,248, filed on Sep. 19, 2018.

(51) Int. Cl. G02F 1/1362; G02F 1/1368; H01L 27/12

(52) U.S. Cl. CPC G02F 1/136209; G02F 1/1368; G02F 1/136286; G02F 2001/13606; G02F 2001/13685; G02F 2202/10; H01L 27/1225

(57) ABSTRACT

An active matrix substrate of a display device includes a substrate, a pixel TFT supported on a major surface side of the substrate, a gate line extending in a first direction, and a source line extending in a second direction that intersects to the first direction. The pixel TFT is a top gate configuration TFT that includes an oxide semiconductor layer which includes a channel region and a gate electrode which is electrically coupled with the gate line and which is provided on the oxide semiconductor layer with a gate insulating layer interposed therebetween. The active matrix substrate further includes a light shielding line which is provided between the substrate and the oxide semiconductor layer and which is provided with a predetermined potential. The light shielding line includes a channel shielding portion which shields the channel region of the oxide semiconductor layer from light and a non-overlapping portion which includes a portion extending in the first direction and which does not overlap the gate line.

### BACKGROUND

### 1. Technical Field

The present invention relates to a display device and particularly to a display device which includes oxide semiconductor TFTs as switching elements of an active matrix substrate.

### 2. Description of the Related Art

Presently, display devices which include an active matrix substrate which includes switching elements in respective pixels have been widely used. An active matrix substrate which includes thin film transistors (hereinafter, “TFT(s)”) as switching elements is referred to as a TFT substrate. In this specification, a region of the TFT substrate corresponding to a pixel of the display device is also referred to as a pixel. A TFT which is provided as a switching element in each pixel of an active matrix substrate is also referred to as “pixel TFT”.

In recent years, using an oxide semiconductor as a material of the active layer of TFTs, instead of amorphous silicon and polycrystalline silicon, has been proposed. A TFT which includes an oxide semiconductor film as the active layer is referred to as “oxide semiconductor TFT”. Patent Document No. 1 (Japanese Laid-Open Patent Publication No. 2012-134475) discloses an active matrix substrate in which an In—Ga—Zn—O based semiconductor film is used for the active layer of a TFT.

The oxide semiconductor has higher mobility than the amorphous silicon. Therefore, oxide semiconductor TFTs are capable of higher speed operation than amorphous silicon TFTs. Further, oxide semiconductor films can be formed through a simpler and more convenient process than polycrystalline silicon films and are therefore applicable to devices which require large surfaces.

The configuration of TFTs can be generally classified into “bottom gate configuration” and “top gate configuration”. Presently, although many oxide semiconductor TFTs employ the bottom gate configuration, using the top gate configuration has also been proposed (for example, Patent Document No. 2: Japanese Laid-Open Patent Publication No. 2012-204077). In the top gate configuration, the thickness of the gate insulating layer can be reduced and, therefore, high current supply performance can be achieved.

In some liquid crystal display devices, a gate driver and an SSD (Source Shared driving) circuit are integrally (monolithically) formed on an active matrix substrate for the purpose of narrowing the frame of the liquid crystal panel and reducing the number of included driver ICs. A gate driver monolithically formed on an active matrix substrate is also referred to as a GDM circuit. In an active matrix substrate on which a GDM circuit and an SSD circuit are monolithically formed, TFTs need to charge a large capacitance (bus line capacitance) and, therefore, it can be said that the TFTs preferably have a top gate configuration. In consideration that the space can be saved for narrowing of the frame, it can also be said that the top gate configuration is preferred.

In a TFT of a top gate configuration, for the purpose of preventing occurrence of current leakage which is attributed to irradiation of a semiconductor layer with light, providing a light shielding layer under the channel region of the semiconductor layer is known. Patent Document No. 3 (Japanese Laid-Open Patent Publication No. 2008-197359) discloses a liquid crystal display device which has a structure capable of controlling the potential of such a light shielding layer (i.e., capable of inputting a signal from an external device into the light shielding layer). By appropriately controlling the potential of the light shielding layer, the TFT characteristics can be improved, for example, the off-leak current can be reduced.

### SUMMARY

In the liquid crystal display device of Patent Document No. 3, the light shielding layer is supplied with a signal from a control line which is integrally formed with the light shielding layer. However, the control line extends in the same direction as a scan line so as to overlap the scan line and, therefore, the load of the scan line (capacitive load) increases and the dullness of the scan signal increases. As a result, luminance unevenness is likely to occur.

The present invention was conceived in view of the above-described problems. An object of the present invention is to suppress, in a display device which includes oxide semiconductor TFTs, occurrence of luminance unevenness which is attributed to a line provided for improvement in the TFT characteristics (e.g., a light shielding line which includes a portion shielding the channel region of the TFTs from light).

This specification discloses display devices as set forth in the following items.

[Item 1]

A display device comprising an active matrix substrate and having a plurality of pixel regions, the active matrix substrate including

a substrate which has a major surface,

a pixel TFT supported on a major surface side of the substrate and arranged so as to correspond to respective one of the plurality of pixel regions,

a gate line extending in a first direction that supplies a gate signal to the pixel TFT, and

a source line extending in a second direction that supplies a source signal to the pixel TFT, the second direction intersecting to the first direction,

wherein the pixel TFT is a top gate configuration TFT that includes an oxide semiconductor layer which includes a channel region and a gate electrode which is electrically coupled with the gate line and which is provided on the oxide semiconductor layer with a gate insulating layer interposed therebetween,

the active matrix substrate further includes a light shielding line which is provided between the substrate and the oxide semiconductor layer and which is made of an electrically-conductive material that has a light shielding property, the light shielding line being provided with a predetermined potential, and

the light shielding line includes a channel shielding portion which shields the channel region of the oxide semiconductor layer from light and a non-overlapping portion which includes a portion extending in the first direction and which does not overlap the gate line when viewed in a direction normal to the major surface of the substrate.

### [Item 2]

The display device as set forth in Item 1, wherein the predetermined potential provided to the light shielding line is a fixed potential.

### [Item 3]

The display device as set forth in Item 1 or Item 2, wherein the non-overlapping portion of the light shielding line which includes the channel shielding portion that shields from light the channel region of the pixel TFT corresponding to one of the plurality of pixel regions is present outside that pixel region.

[Item 4]

The display device as set forth in any of Item 1 to Item 3 further comprising a black matrix, wherein when viewed in a direction normal to the major surface of the substrate, an approximate entirety of the light shielding line overlaps the black matrix.

[Item 5]

The display device as set forth in any of Item 1 to Item 4, wherein

the pixel TFT further includes a source electrode and a drain electrode which are electrically coupled with the oxide semiconductor layer,

the source electrode is connected with the source line, and

when viewed in a direction normal to the major surface of the substrate, the non-overlapping portion of the light shielding line is present on the drain electrode side relative to the gate line.

[Item 6]

The display device as set forth in Item 5, wherein when viewed in a direction normal to the major surface of the substrate, the non-overlapping portion of the light shielding line is present between the gate line and the drain electrode.

[Item 7]

The display device as set forth in Item 6, wherein the oxide semiconductor layer further includes a first low-resistance region which is present on the source electrode side of the channel region and which has a lower specific resistance than the channel region and a second low-resistance region which is present on the drain electrode side of the channel region and which has a lower specific resistance than the channel region, and

when viewed in a direction normal to the major surface of the substrate, the light shielding line includes a portion which overlaps a part of the second low-resistance region of the oxide semiconductor layer.

[Item 8]

The display device as set forth in Item 5, wherein

the oxide semiconductor layer further includes a first low-resistance region which is present on the source electrode side of the channel region and which has a lower specific resistance than the channel region and a second low-resistance region which is present on the drain electrode side of the channel region and which has a lower specific resistance than the channel region, and

when viewed in a direction normal to the major surface of the substrate, the light shielding line includes a portion which overlaps a part of the second low-resistance region of the oxide semiconductor layer and a part of the drain electrode.

[Item 9]

The display device as set forth in Item 5, wherein

the oxide semiconductor layer further includes a first low-resistance region which is present on the source electrode side of the channel region and which has a lower specific resistance than the channel region and a second low-resistance region which is present on the drain electrode side of the channel region and which has a lower specific resistance than the channel region, and

when viewed in a direction normal to the major surface of the substrate, the light shielding line includes a portion which overlaps an approximate entirety of the second low-resistance region of the oxide semiconductor layer and an approximate entirety of the drain electrode.

[Item 10]

The display device as set forth in any of Item 1 to Item 9, wherein the light shielding line does not overlap a region in which the gate line and the source line intersect each other.

[Item 11]

A display device comprising an active matrix substrate and having a plurality of pixel regions, the active matrix substrate including

a substrate which has a major surface,

a pixel TFT supported on a major surface side of the substrate and arranged so as to correspond to respective one of the plurality of pixel regions,

a gate line extending in a first direction that supplies a gate signal to the pixel TFT, and

a source line extending in a second direction that supplies a source signal to the pixel TFT, the second direction intersecting to the first direction,

wherein the pixel TFT is a bottom gate configuration TFT that includes an oxide semiconductor layer which includes a channel region and a gate electrode which is electrically coupled with the gate line and which is provided under the oxide semiconductor layer with a gate insulating layer interposed therebetween,

the active matrix substrate further includes an upper line provided above the oxide semiconductor layer, the upper line being provided with a predetermined potential, and

the upper line includes a channel overlapping portion which overlaps the channel region of the oxide semiconductor layer when viewed in a direction normal to the major surface of the substrate and a non-overlapping portion which includes a portion extending in the first direction and which does not overlap the gate line when viewed in a direction normal to the major surface of the substrate.

[Item 12]

The display device as set forth in any of Item 1 to Item 11, wherein the oxide semiconductor layer contains an In—Ga—Zn—O based semiconductor.

[Item 13]

The display device as set forth in Item 12, wherein the In—Ga—Zn—O based semiconductor includes a crystalline portion.

[Item 14]

The display device as set forth in any of Item 1 to Item 13, further comprising:

a counter substrate arranged so as to oppose the active matrix substrate; and

a liquid crystal layer provided between the active matrix substrate and the counter substrate.

According to an embodiment of the present invention, in a display device which includes oxide semiconductor TFTs, occurrence of luminance unevenness which is attributed to a line provided for improvement in the TFT characteristics (e.g., a light shielding line which includes a portion shielding the channel region of the TFTs from light) can be suppressed.

### BRIEF DESCRIPTION OF THE DRAWINGS

FIG. 1 is a cross-sectional view schematically showing a liquid crystal display device 100 of an embodiment of the present invention.

FIG. 2 is an overview showing an example of the planar configuration of an active matrix substrate 10 included in the liquid crystal display device 100.

FIG. 3 is an equivalent circuit diagram of a pixel region PIX of the active matrix substrate 10.

FIG. 4 is a plan view illustrating the pixel region PIX of the active matrix substrate 10.

FIG. 5 is a cross-sectional view taken along line V-V′ of FIG. 4.

FIG. 6 is a cross-sectional view taken along line VI-VI′ of FIG. 4.

FIG. 7 is a schematic cross-sectional view showing an example of the configuration of a color filter substrate 20 included in the liquid crystal display device 100.

FIG. 8 is a plan view showing a pixel region PIX of an active matrix substrate 910 of a reference example.

FIG. 9 is a cross-sectional view taken along line IX-IX′ of FIG. 8.

FIG. 10 is a flowchart showing an example of the manufacturing method of the active matrix substrate 10.

FIG. 11 is an overview showing an example of the planar configuration of an alternative active matrix substrate 10A included in a liquid crystal display device of an embodiment of the present invention.

FIG. 12 is a cross-sectional view taken along line XII-XII′ of FIG. 11.

FIG. 13 is an overview showing an example of the planar configuration of a still alternative active matrix substrate 10B included in a liquid crystal display device of an embodiment of the present invention.

FIG. 14 is a cross-sectional view taken along line XIV-XIV′ of FIG. 13.

FIG. 15 is a diagram showing regions sc1 and sc2 in which additional storage capacitor is formed by a light shielding line LsL.

FIG. 16 is an overview showing an example of the planar configuration of a still alternative active matrix substrate 10C included in a liquid crystal display device of an embodiment of the present invention.

FIG. 17 is a cross-sectional view taken along line XVII-XVII′ of FIG. 16.

FIG. 18 is a diagram showing regions sc1 and sc2 in which additional storage capacitor is formed by a light shielding line LsL.

FIG. 19 is an overview showing an example of the planar configuration of a still alternative active matrix substrate 10D included in a liquid crystal display device of an embodiment of the present invention.

FIG. 20 is an overview showing an example of the planar configuration of a still alternative active matrix substrate 10E included in a liquid crystal display device of an embodiment of the present invention.

FIG. 21 is a cross-sectional view taken along line XXI-XXI′ of FIG. 20.

### DETAILED DESCRIPTION

Hereinafter, embodiments of the present invention are described with reference to the drawings. In the following sections, a liquid crystal display device is illustrated as a display device of an embodiment of the present invention, although the present invention is not limited to the following embodiments.

### Embodiment 1

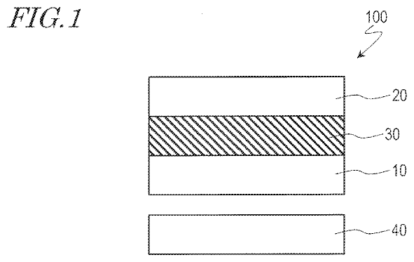

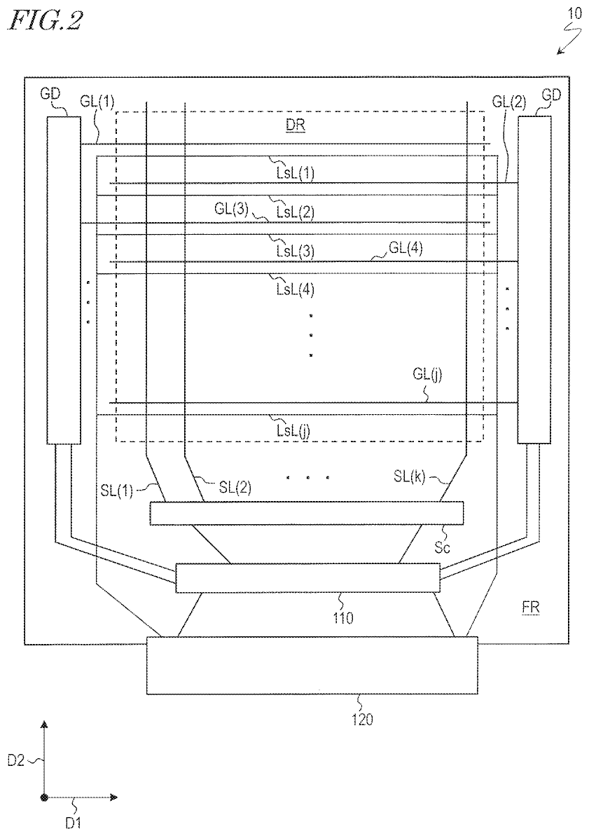

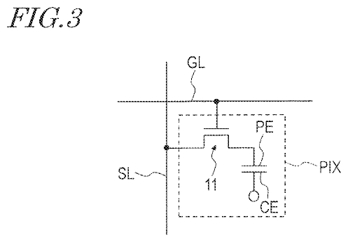

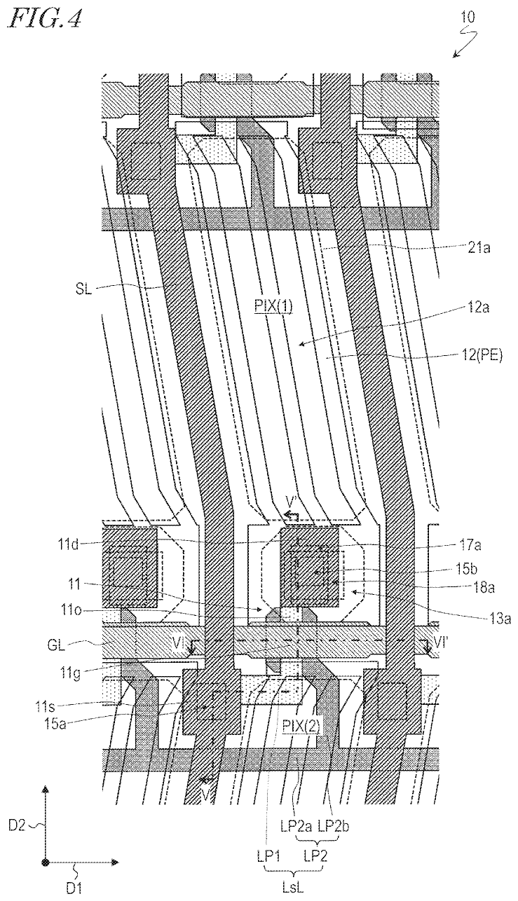

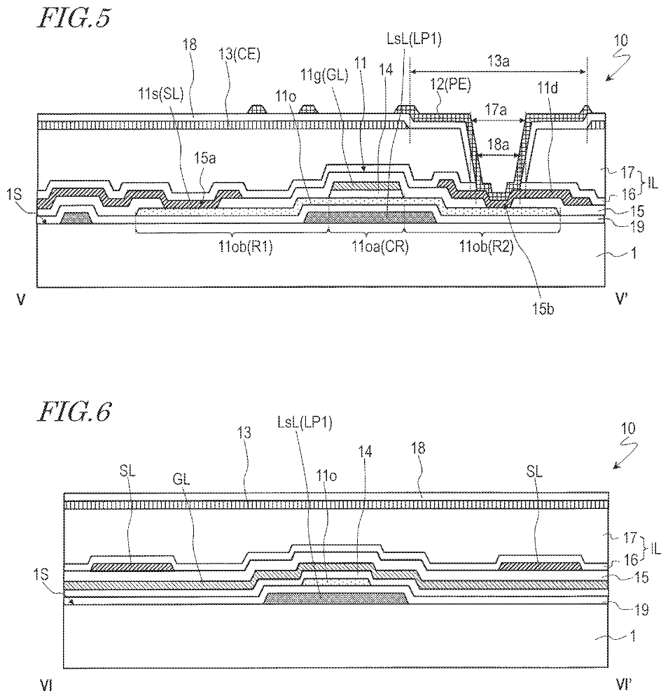

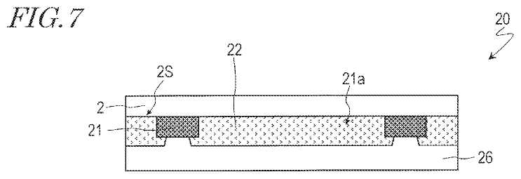

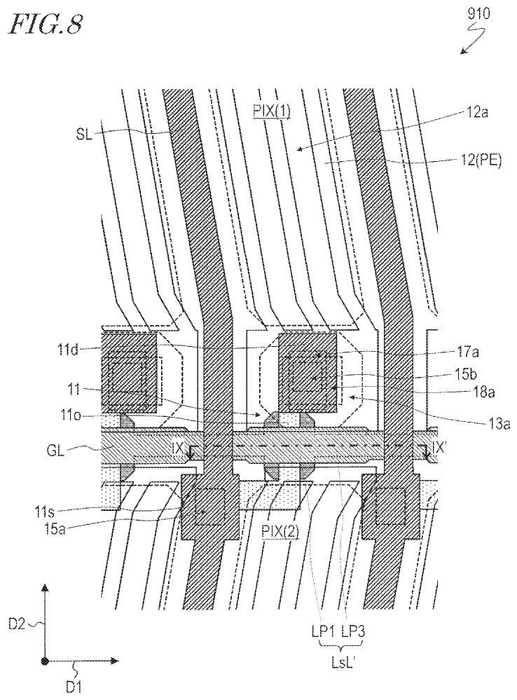

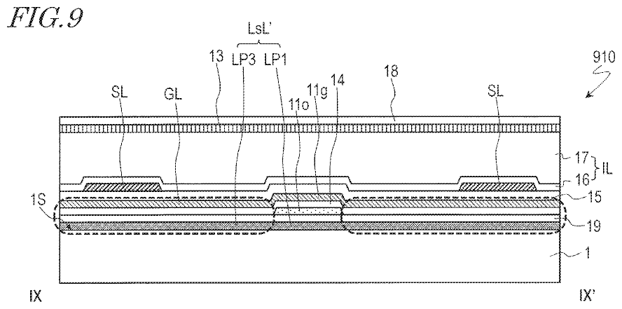

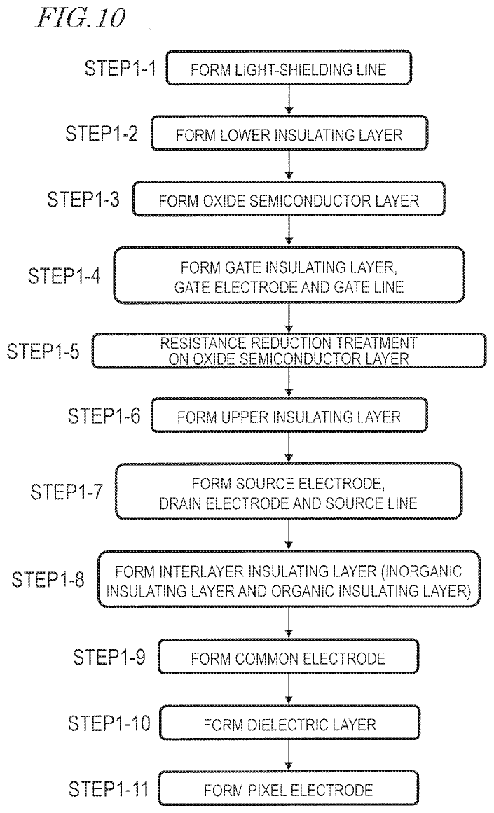

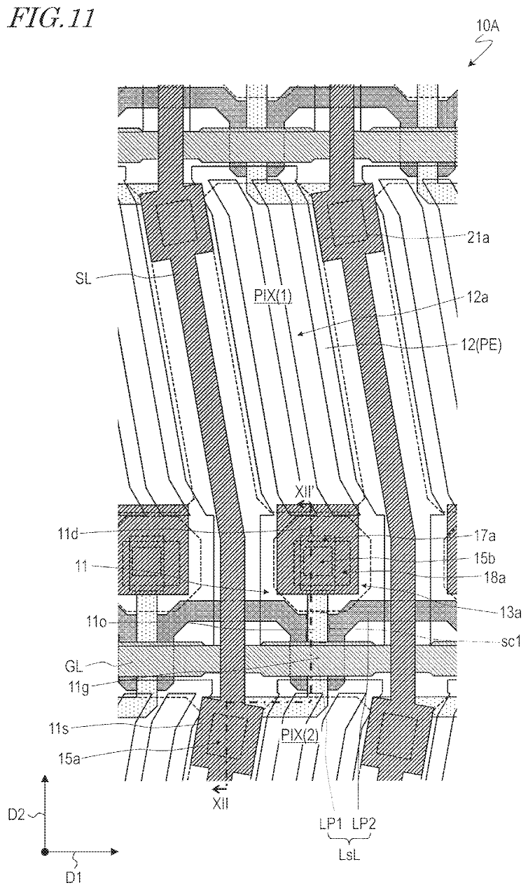

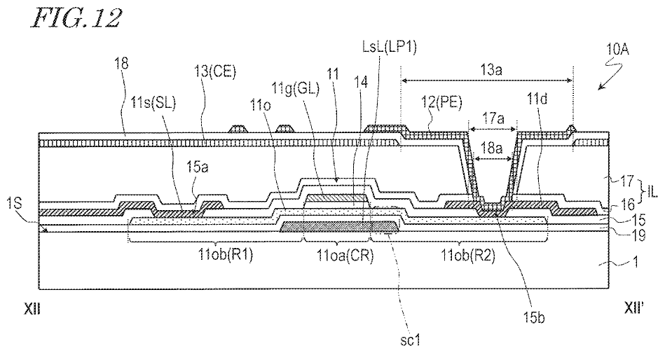

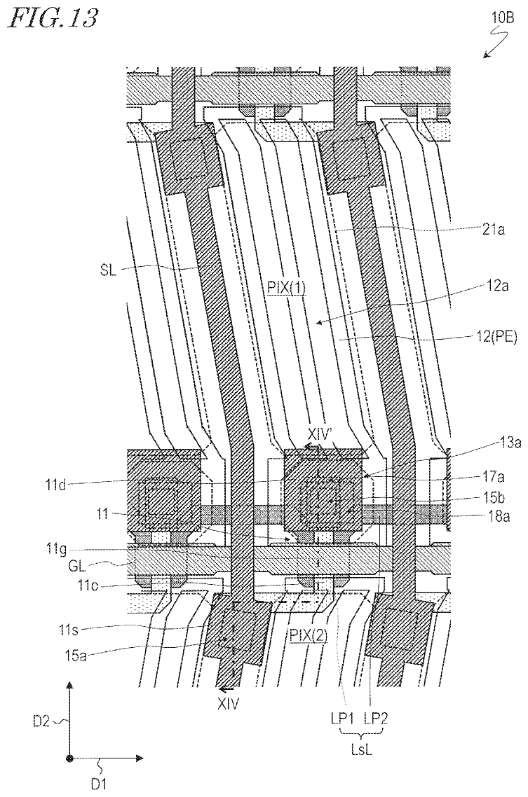

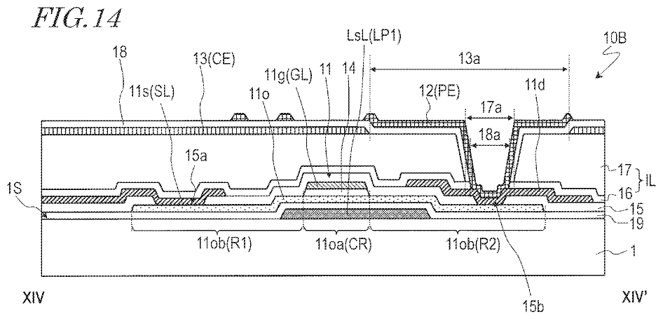

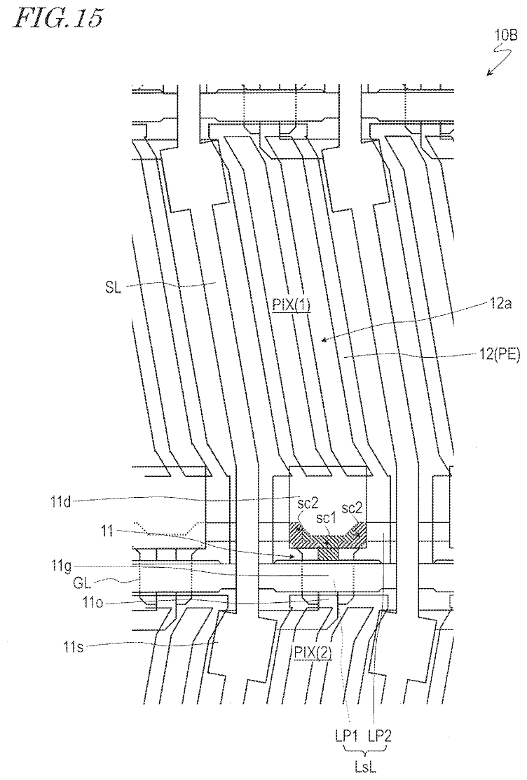

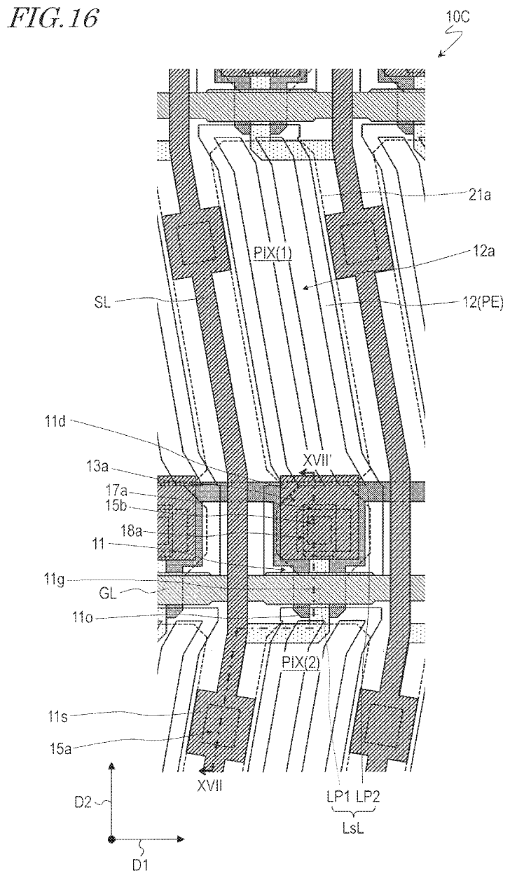

A liquid crystal display device 100 of the present embodiment is described with reference to FIG. 1. FIG. 1 is a cross-sectional view schematically showing the liquid crystal display device 100.

As shown in FIG. 1, the liquid crystal display device 100 includes an active matrix substrate 10, a counter substrate 20 which is arranged so as to oppose the active matrix substrate 10, and a liquid crystal layer 30 which is provided between the active matrix substrate 10 and the counter substrate 20. The liquid crystal display device 100 further includes a backlight (lighting device) 40 which is located on the rear side of the active matrix substrate 10 (on the side opposite to the viewer side).

The configuration of the active matrix substrate 10 is described with reference to FIG. 2 and FIG. 3. In the configuration illustrated below, a gate driver and a source shared driving (SSD) circuit are monolithically provided.

FIG. 2 is an overview showing an example of the planar configuration of the active matrix substrate 10. As shown in FIG. 2, the active matrix substrate 10 has a display region DR and a region FR exclusive of the display region DR (which is referred to as “non-display region” or “frame region”). The display region DR is defined by a plurality of pixel regions arranged in a matrix. Each of the pixel regions (also simply referred to as “pixels”) is a region corresponding to a single pixel of the liquid crystal display device 100. The non-display region FR is a region which lies around the display region DR and which does not contribute to displaying.

In the display region DR, a plurality of gate lines GL(1) to GL(j) extending in the first direction (row direction) D1 (j is an integer not less than 2: hereinafter, generically referred to as “gate lines GL”) and a plurality of source lines SL(1) to SL(k) extending in the second direction (column direction) D2 that is not parallel to (typically, orthogonal to) the first direction D1 (k is an integer not less than 2: hereinafter, generically referred to as “source lines SL”) are provided.

FIG. 3 is a diagram showing the equivalent circuit of a single pixel region PIX.

Each pixel region PIX includes a thin film transistor (pixel TFT) 11 and a pixel electrode PE as shown in FIG. 3. The gate electrode of the pixel TFT 11 is electrically coupled with a corresponding one of the gate lines GL. The source electrode of the pixel TFT 11 is electrically coupled with a corresponding one of the source lines SL. The drain electrode of the pixel TFT 11 is electrically coupled with the pixel electrode PE. When the display mode is a transverse electric field mode such as FFS (Fringe Field Switching) mode, the active matrix substrate 10 includes an electrode CE which is common for a plurality of pixels (common electrode). When the display mode is a vertical electric field mode, the common electrode CE is provided in the counter substrate 20.

In the example shown in FIG. 2, in the non-display region FR, gate drivers GD for driving the gate lines GL are integrally (monolithically) provided. The gate lines GL are connected with respective terminals of the gate drivers GD. In the non-display region FR, an SSD circuit Sc for driving the source bus lines SL in a time division manner is integrally provided. The source lines SL are connected with respective terminals of the SSD circuit Sc.

In this example, a driver IC 110, which includes a source driver, a timing controller, etc., is mounted to the active matrix substrate 10. The gate driver (GDM circuit) GD and the SSD circuit Sc are each supplied with a signal from the driver IC 110. The driver IC 110 is supplied with a signal from a flexible printed circuit (FPC) board 120.

The SSD circuit Sc is a circuit for distributing video data from a single video signal line connected with respective terminals of the source driver to a plurality of source lines. Due to inclusion of the SSD circuit Sc, a part of the non-display region FR in which terminal portions are to be provided (terminal portion formation region) can be further narrowed. Further, the number of outputs from the source driver decreases, and the circuit scale can be reduced. Thus, the cost of the driver IC 110 can be reduced.

In the present embodiment, in the display region DR, as shown in FIG. 2, a plurality of light shielding lines LsL(1) to LsL(j) (hereinafter, generically referred to as “light shielding lines LsL”) extending in the first direction D1 are provided. The light shielding lines LsL are made of an electrically-conductive material which has a light shielding property and are provided with a predetermined potential (i.e., supplied with a signal from an external device). In the example shown in FIG. 2, the light shielding lines LsL are supplied with a signal from FPC 120.

Next, the configuration of the pixel region PIX is specifically described with an example of an active matrix substrate for use in an FFS mode liquid crystal display device.

FIG. 4 is a plan view illustrating the pixel region PIX of the active matrix substrate 10. FIG. 5 and FIG. 6 are cross-sectional views respectively taken along line V-V′ and line VI-VI′ of FIG. 4.

In the illustrated example, the pixel region PIX is a region enclosed by two source lines SL which are neighboring each other and two gate lines GL which are neighboring each other.

As shown in FIG. 4, FIG. 5 and FIG. 6, the active matrix substrate 10 includes a substrate 1 which has a major surface 1S, pixel TFTs 11 supported by the major surface 1S side of the substrate 1, gate lines GL that supplies gate signals to the pixel TFTs 11, and source lines SL that supplies source signals to the pixel TFTs 11. The active matrix substrate 10 further includes an upper transparent electrode 12 (herein, the pixel electrode PE) and a lower transparent electrode 13 (herein, the common electrode CE). The active matrix substrate 10 further includes light shielding lines LsL.

The pixel TFTs 11 correspond to respective ones of a plurality of pixel regions PIX. In the present embodiment, the pixel TFTs 11 are TFTs of a top gate configuration.

The pixel TFT 11 includes an oxide semiconductor layer 11o which includes a channel region CR and a gate electrode 11g which is provided on the oxide semiconductor layer 11o with a gate insulating layer 14 interposed therebetween. The pixel TFT 11 further includes a source electrode 11s and a drain electrode 11d which are electrically coupled with the oxide semiconductor layer 11o.

The gate electrode 11g is electrically coupled with the gate line GL. In this example, a part of the gate line GL, more specifically a part of the gate line GL which overlaps the oxide semiconductor layer 11o when viewed in a direction normal to the major surface 1S of the substrate 1 (hereinafter, referred to as “substrate-normal direction”), functions as the gate electrode 11g. Alternatively, a portion extended from the gate line GL (for example, a portion extending along the second direction D2) may be formed such that the extended portion functions as the gate electrode 11g.

The source electrode 11s is electrically coupled with the source line SL. In this example, a part of the source line SL, more specifically a part of the source line SL which overlaps the oxide semiconductor layer 11o when viewed in the substrate-normal direction, functions as the source electrode 11s. Alternatively, a portion extended from the source line SL (for example, a portion extending along the first direction D1) may be formed such that the extended portion functions as the source electrode 11s.

The drain electrode 11d is electrically coupled with the pixel electrode 12. In the illustrated example, the drain electrode 11d is formed by the same electrically-conductive film (source metal film) as the source line SL and the source electrode 11s.

On the oxide semiconductor layer 11o, a gate insulating layer 11g is provided so as to overlap a part of the oxide semiconductor layer 11o when viewed in the substrate-normal direction.

Part 11ob of the oxide semiconductor layer 11o which does not overlap the gate insulating layer 14 (or the gate electrode 11g) when viewed in the substrate-normal direction is a low-resistance region whose specific resistance is smaller than that of the part 11oa overlapping the gate insulating layer 14 (and the gate electrode 11g). The low-resistance region 11ob can be formed by performing, for example, a resistance reduction treatment on the oxide semiconductor layer 11o using the gate electrode 11g and the gate insulating layer 14 as masks. The part 11oa which is masked under the gate electrode 11g and the gate insulating layer 14 and whose resistance is not reduced is referred to as “first semiconductor region”. In this example, the entirety of the first semiconductor region 11oa forms the channel region CR in which the channel of the pixel TFT 11 is formed. The low-resistance regio 11ob includes a first low-resistance region R1 located on the source electrode 11s side of the channel region CR and a second low-resistance region R2 located on the drain electrode 11d side of the channel region CR.

On the oxide semiconductor layer 11o, the gate insulating layer 14 and the gate electrode 11g, an upper insulating layer 15 is provided. The source electrode 11s is provided on the upper insulating layer 15 and inside an opening 15a formed in the upper insulating layer 15 (source side opening) and is connected with a part of an oxide semiconductor layer 11c (herein, a part of the first low-resistance region R1) inside the source side opening 15a. Likewise, the drain electrode 11d is provided on the upper insulating layer 15 and inside an opening 15b formed in the upper insulating layer 15 (drain side opening) and is connected with another part of the oxide semiconductor layer 11o (herein, a part of the second low-resistance region R2) inside the drain side opening 15b.

The pixel TFT 11 is covered with an interlayer insulating layer IL. In this example, the interlayer insulating layer IL has a multilayer structure which includes an inorganic insulating layer 16 and an organic insulating layer 17 provided on the inorganic insulating layer 16.

On the interlayer insulating layer IL, the lower transparent electrode 13 is provided. On the lower transparent electrode 13, the upper transparent electrode 12 is provided with a dielectric layer 18 interposed therebetween. One of the lower transparent electrode 13 and the upper transparent electrode 12 (herein, the upper transparent electrode 12) functions as the pixel electrode PE, while the other (herein, the lower transparent electrode 13) functions as the common electrode CE. The pixel electrode PE is divided into respective pixels. The common electrode CE may not be divided into respective pixels.

The pixel electrode PE is electrically coupled with the drain electrode 11d of the pixel TFT 11. Herein, the pixel electrode PE is connected with the drain electrode 11d inside a pixel contact hole formed in the interlayer insulating layer IL and the dielectric layer 18. In the illustrated example, the pixel contact hole consists of an opening 17a formed in the organic insulating layer 17 and an opening 18a formed in the dielectric layer 18 and the inorganic insulating layer 16. The pixel contact hole may partially or entirely overlap the drain side opening 15b.

The pixel electrode PE has at least one slit (or notch) 12a. In this example, the pixel electrode PE has two slits 12a, although the number of slits 12a is not limited to two.

The common electrode CE has an opening 13a above a region in which the pixel contact hole of the pixel TFT 11 is formed, and lies across the entire pixel region PIX except for this region.

In the example shown in FIG. 4, the pixel TFT 11 is arranged such that the channel length direction is identical with the second direction D2 (the extending direction of the source lines SL) (upright-TFT configuration) although, as will be described later, the pixel TFT 11 may be arranged such that the channel length direction is identical with the first direction D1 (the extending direction of the gate lines GL) (recumbent-TFT configuration). In this specification, the channel length direction refers to a direction in which an electric current flows across the channel region in a plane parallel to the major surface 1S of the substrate 1. The channel width direction refers to a direction orthogonal to the channel length direction.

In the example shown in FIG. 4, when viewed in the substrate-normal direction, the oxide semiconductor layer 11o of the pixel TFT 11 of a certain pixel region PIX(1) extends across the gate line GL from a pixel region PIX(2) which is neighboring along the second direction D2 to the pixel region PIX(1). In a part of the oxide semiconductor layer 11o overlapping the gate line GL, the channel region CR is provided. That is, a part of the gate line GL overlapping the oxide semiconductor layer 11o functions as the gate electrode 11g. The first low-resistance region R1 of the oxide semiconductor layer 11o overlaps a part of the source line SL in the pixel region PIX(2) and is connected with the source line SL in the source side opening 15a that is provided in the overlapping part. That is, a part of the source line SL overlapping the oxide semiconductor layer 11o functions as the source electrode 11s. Meanwhile, the second low-resistance region R2 is connected with the drain electrode 11d in the pixel region PIX(1).

The pixel TFT 11 may not have a drain electrode 11d which is made of a source metal. In that case, the pixel electrode PE may be electrically coupled with the oxide semiconductor layer 11o by bringing the pixel electrode PE into direct contact with the second low-resistance region R2 of the oxide semiconductor layer 11o inside the pixel contact hole. Alternatively, the second low-resistance region R2 of the oxide semiconductor layer 11o can also be used as the pixel electrode PE.

The light shielding line LsL is provided between the substrate 1 and the oxide semiconductor layer 11o as shown in FIG. 5 and FIG. 6. In the illustrated example, the light shielding line LsL is provided on the major surface 1S of the substrate 1, and a lower insulating layer 19 is provided so as to cover the light shielding line LsL. On the lower insulating layer 19, the pixel TFT 11 is provided.

The light shielding line LsL includes a channel shielding portion LP1 for shielding the channel region CR of the oxide semiconductor layer 11o from light. When viewed in the substrate-normal direction, the channel shielding portion LP1 overlaps an approximate entirety of the channel region CR and prevents light from the backlight 40 from reaching the channel region CR.

The light shielding line LsL includes a non-overlapping portion LP2 which does not overlap a gate line GL when viewed in the substrate-normal direction. In the illustrated example, the non-overlapping portion LP2 includes a portion LP2a extending in the first direction D1 (trunk portion) LP2a and a portion LP2b extending from the trunk portion LP2a in the second direction D2 and connecting the trunk portion LP2a and the channel shielding portion LP1 (branch portion). Thus, the light shielding line LsL does not overlap the gate line GL in the channel region CR and in the vicinity of the channel region CR. The light shielding line LsL does not overlap a region in which the gate line GL and the source line SL intersect each other.

As shown in FIG. 4, the non-overlapping portion LP2 of the light shielding line LsL which includes the channel shielding portion LP1 that shields from light the channel region CR of the pixel TFT 11 corresponding to a certain pixel region PIX (for example, the pixel region PIX(1) in FIG. 4) is present outside that pixel region PIX, more specifically present in a pixel region PIX which is adjacent to that pixel region PIX along the second direction D2 (for example, the pixel region PIX(2) in FIG. 4).

FIG. 7 is a schematic cross-sectional view showing an example of the configuration of the color filter substrate 20. As shown in FIG. 7, the color filter substrate 20 includes a substrate 2 which has a major surface 2S, and a black matrix 21 and a color filter layer 22 which are supported on the major surface 2S side of the substrate 2.

The black matrix 21 has openings 21a at positions corresponding to the respective pixel regions PIX. That is, the black matrix 21 is in the shape of a lattice. Although FIG. 4 is a diagram showing the active matrix substrate 10, the openings 21a of the black matrix 21 are represented by dotted lines in the drawing for the sake of reference.

The color filter layer 22 is provided at least in the openings 21a of the black matrix 21. The color filter layer 22 typically includes a red color filter, a green color filter and a blue color filter. In the illustrated example, an overcoat layer (flattening layer) 26 is provided so as to cover the black matrix 21 and the color filter layer 22.

As described above, in the liquid crystal display device 100 of the present embodiment, the active matrix substrate 10 includes the light shielding line LsL that includes the channel shielding portion LP1 and, therefore, the channel shielding portion LP1 of the light shielding line LsL can shield the channel region CR of the pixel TFT 11 from light. Since the light shielding line LsL is provided with a predetermined potential (i.e., supplied with a signal from an external device), it is possible to control the signal potential on the non-control side of the pixel TFT 11 (in other words, the electric field environment opposite to the gate electrode 11g relative to the oxide semiconductor layer 11o) and stabilize the TFT characteristics. For example, the OFF state in holding the pixel potential (the display signal voltage applied to the pixel electrode PE) can be made more stable (the off-leak current can be reduced).

The non-overlapping portion LP2, which is the other part of the light shielding line LsL than the channel shielding portion LP1, does not overlap the gate line GL and, therefore, dulling of the scan signal and occurrence of luminance unevenness which are attributed to the increase in load of the gate line GL are prevented. Hereinafter, this point is described in comparison with an active matrix substrate 910 of a reference example shown in FIG. 8 and FIG. 9.

FIG. 8 is a plan view showing a pixel region PIX of the active matrix substrate 910 of the reference example. FIG. 9 is a cross-sectional view taken along line IX-IX′ of FIG. 8. The active matrix substrate 910 of the reference example includes light shielding lines LsL′ whose configuration is different from that of the light shielding lines LsL of the active matrix substrate 10 shown in FIG. 4 and other drawings.

As shown in FIG. 8 and FIG. 9, the light shielding line LsL′ of the active matrix substrate 910 of the reference example includes a channel shielding portion LP1 for shielding the channel region CR of the oxide semiconductor layer 11o from light and an overlapping portion LP3 which extends in the first direction D1 and overlaps the gate line GL when viewed in the substrate-normal direction.

Thus, in the active matrix substrate 910 of the reference example, a part of the light shielding line LsL′ other than the channel shielding portion LP1 (overlapping portion LP3) overlaps the gate line GL and, therefore, the overlap area of the light shielding line LsL′ and the gate line GL greatly increase (see regions enclosed by broken lines in FIG. 9) so that, unfavorably, a large capacitance can be formed between the light shielding line LsL′ and the gate line GL. Thus, the load of the gate line GL increases, and a pixel charging failure can occur due to the dullness of the gate signal. Also, the load of the light shielding line LsL′ increases and, therefore, it is difficult to stabilize the potential by inputting an external signal to the light shielding line LsL′, and it is difficult to stabilize the TFT characteristics.

In comparison, in the active matrix substrate 10 of the liquid crystal display device 100 of the present embodiment, the overlap area of the gate line GL and the light shielding line LsL can be set to an amount which is necessary and sufficient for shielding the channel region CR from light (for example, can be minimized) and, therefore, the gate signal can be supplied without dulling (or without greatly dulling) the waveform of the gate signal. Further, supply of signals to the light shielding line LsL can be stably carried out and, therefore, stabilization of the TFT characteristics can be suitably realized.

As for the reference example shown in FIG. 8 and FIG. 9, the overlap area of the gate line GL (including the gate electrode 11g) and the light shielding line LsL′ was calculated as a trial, and it was 74 μm² per pixel. In comparison, as for the example shown in FIG. 4. FIG. 5 and FIG. 6, the overlap area of the gate line GL (including the gate electrode 11g) and the light shielding line LsL was calculated as a trial, and it was 20 μm² per pixel. This means that the capacitance formed between the light shielding line LsL and the gate line GL was reduced by 70% or more.

From the viewpoint of reducing the load of the light shielding line LsL, it is preferred that the light shielding line LaL does not overlap the other lines or electrodes than the gate line GL as much as possible. For example, as shown in FIG. 4, it is preferred that the light shielding line LsL does not overlap the first low-resistance region R1 (the low-resistance region on the source electrode his side) of the oxide semiconductor layer 11o.

[Signal Input to Light Shielding Line]

Although the potential applied to the light shielding line LsL is not particularly limited, it is preferred from the viewpoint of stabilizing the TFT characteristics that the potential applied to the light shielding line LsL is a fixed potential. Specifically, for example, the low-level potential of the gate signal, the GND (ground potential), and a potential between these potentials can be used as the fixed potential.

[Variations]

In the foregoing description, the display mode is the FFS mode. The FFS mode is a transverse electric field mode where a pair of electrodes are provided in one substrate and an electric field is applied across the liquid crystal molecules in a direction parallel to the substrate surface (transverse direction). In this example, an electric field represented by electric lines of force which come out from the pixel electrode PE, passes through the liquid crystal layer (not shown) and then through a slit-like opening of the pixel electrode PE, and reach the common electrode CE. This electric field includes a component of the transverse direction with respect to the liquid crystal layer. As a result, the electric field of the transverse direction can be applied across the liquid crystal layer. In the transverse direction electric field mode, the liquid crystal molecules do not rise from the substrate and, therefore, advantageously, a wide viewing angle can be realized as compared with the vertical electric field mode.

An electrode structure in which the pixel electrode PE is provided on the common electrode CE with the dielectric layer 18 interposed therebetween is disclosed in, for example, WO 2012/086513. Note that the common electrode CE may be provided on the pixel electrode PE with the dielectric layer 18 interposed therebetween. That is, the lower transparent electrode 13 may be the pixel electrode PE, and the upper transparent electrode 12 may be the common electrode CE. Such an electrode structure is disclosed in, for example, Japanese Laid-Open Patent Publication No. 2008-032899 and Japanese Laid-Open Patent Publication No. 2010-008758. The entire disclosures of WO 2012/086513, Japanese Laid-Open Patent Publication No. 2008-032899 and Japanese Laid-Open Patent Publication No. 2010-008758 are incorporated by reference in this specification.

The IPS mode is also known as a transverse direction electric field mode other than the FFS mode. A liquid crystal display device of an embodiment of the present invention may perform displaying in the IPS mode. The active matrix substrate of a liquid crystal display device of an embodiment of the present invention may not include the common electrode CE. Such an active matrix substrate can be used in a liquid crystal display device of the TN (Twisted Nematic) mode, VA (Vertical Alignment) mode, or the like. The VA mode and the TN mode are vertical direction electric field modes where a pair of electrodes with the liquid crystal layer interposed therebetween are used to apply an electric field across liquid crystal molecules.

The embodiments of the present invention are not limited to liquid crystal display devices but are applicable to other types of display devices.

[Manufacturing Method of Active Matrix Substrate 10]

Hereinafter, an example of the manufacturing method of the active matrix substrate 10 is described with reference to FIG. 4 to FIG. 6 and FIG. 10. FIG. 10 is a flowchart showing an example of the manufacturing method of the active matrix substrate 10.

Step1-1

Firstly, a light shielding line LaL which includes a channel shielding portion LP1 and a non-overlapping portion LP2 is formed on a substrate 1.

As the substrate 1, for example, a glass substrate, a silicon substrate, a heat-resistant plastic substrate (resin substrate), or the like, can be used.

The light shielding line LsL is realized by, for example, forming an electrically-conductive film for the light shielding line (thickness: for example, not less than 50 nm and not more than 500 nm) by sputtering, and patterning the electrically-conductive film for the light shielding line.

As the electrically-conductive film for the light shielding line, a metal film which includes an element selected from aluminum (Al), chromium (Cr), copper (Cu), tantalum (Ta), titanium (Ti), molybdenum (Mo) and tungsten (W), an alloy film which includes these elements as constituents, or the like, can be used. Alternatively, a multilayer film which includes a plurality of such films may be used. For example, a multilayer film which has a three-layer structure of titanium film/aluminum film/titanium film or a three-layer structure of molybdenum film/aluminum film/molybdenum film can be used. The electrically-conductive film for the light shielding line is not limited to the three-layer structure but may have a single-layer or two-layer structure or a multilayer structure consisting of four or more layers. Herein, as the electrically-conductive film for the light shielding line, a multilayer film is used which includes a Ti film (thickness: 15-70 nm) as the lower layer and a Cu film (thickness: 200-400 nm) as the upper layer.

Step1-2

Then, a lower insulating layer (thickness: for example, not less than 200 nm and not more than 600 nm) 19 is formed so as to cover the light shielding line LsL.

As the lower insulating layer 19, a silicon oxide (SiOx) layer, a silicon nitride (SiNx) layer, a silicon oxynitride (SiOxNy; x>y) layer, a silicon nitroxide (SiNxOy; x>y) layer, an aluminum oxide layer or a tantalum oxide layer can be appropriately used. The lower insulating layer 19 may have a multilayer structure. Herein, as the lower insulating layer 19, for example, a multilayer film is formed by CVD which includes a silicon nitride (SiNx) layer (thickness: 50-600 nm) as the lower layer and a silicon oxide (SiO₂) layer (thickness: 50-600 nm) as the upper layer. When an oxide film, such as silicon oxide film, is used as the lower insulating layer 19 (if the lower insulating layer 19 has a multilayer structure, as the uppermost layer of the multilayer structure), oxygen deficiencies in the channel region CR of the oxide semiconductor layer 11o that is formed in a subsequent step can be reduced by the oxide film and, therefore, decrease in resistance of the channel region CR can be suppressed.

Step1-3

Then, on the lower insulating layer 19, an oxide semiconductor film (thickness: for example, not less than 15 nm and not more than 200 nm) is formed by, for example, sputtering, and patterning of the oxide semiconductor film is performed, whereby an oxide semiconductor layer 11o is formed. The oxide semiconductor film may be, for example, an In—Ga—Zn—O based semiconductor film although it is not particularly limited.

Step1-4

Then, an insulating film (thickness: for example, not less than 80 nm and not more than 250 nm) and an electrically-conductive film for the gate (thickness: for example, not less than 50 nm and not more than 500 nm) are formed in this order so as to cover the oxide semiconductor layer 11o. The electrically-conductive film for the gate can be formed by, for example, sputtering. The insulating film can be formed by, for example, CVD.

As the insulating film, an insulating film which is similar to the lower insulating layer 19 (the insulating film illustrated as the lower insulating layer 19) can be used. When an oxide film such as silicon oxide film is used as the insulating film, oxygen deficiencies in the channel region CR of the oxide semiconductor layer 11o can be reduced by the oxide film and, therefore, decrease in resistance of the channel region CR can be suppressed. As the electrically-conductive film for the gate, an electrically-conductive film which is similar to the electrically-conductive film for the light shielding line can be used. Herein, as the insulating film, for example, a silicon oxide (SiO₂) film is used. As the electrically-conductive film for the gate, for example, a multilayer film is used which includes a Ti film (thickness: 15-70 nm) as the lower layer and a Cu film (thickness: 200-400 nm) as the upper layer.

Then, patterning of the electrically-conductive film for the gate is performed using an unshown resist mask, whereby a gate electrode 11g and a gate line GL are formed. The patterning of the electrically-conductive film for the gate can be realized by wet etching or dry etching.

Thereafter, patterning of the insulating film is performed using the above-described resist mask. Alternatively, after the above-described resist mask is removed, patterning of the insulating film may be performed using the patterned gate electrode 11g as the mask. Thereby, a gate insulating layer 14 is formed. The patterning of the insulating film can be realized by, for example, dry etching.

In patterning the insulating film, the surface portion of a part of the lower insulating layer 19 which is not covered with the oxide semiconductor layer 11o can be etched away (overetching).

In this step, patterning of the insulating film and patterning of the electrically-conductive film for the gate are performed using the same mask and, therefore, the lateral surfaces of the gate insulating layer 14 and the lateral surfaces of the gate electrode 11g are in agreement with each other in the thickness direction. That is, when viewed in the substrate-normal direction, the periphery of the gate insulating layer 14 is in agreement with the periphery of the gate electrode 11g.

Step1-5

Then, a resistance reduction treatment is performed on the oxide semiconductor layer 11o. The resistance reduction treatment may be, for example, a plasma treatment. As a result, when viewed in the substrate-normal direction, a region 11ob of the oxide semiconductor layer 11o which does not overlap the gate electrode 11g or the gate insulating layer 14 is a low-resistance region whose specific resistance is lower than that of the region 11oa that overlaps the gate electrode 11g and the gate insulating layer 14. The low-resistance region 11ob may be an electrical conductor (for example, sheet resistance: not more than 200Ω/□).

In the resistance reduction treatment (plasma treatment), a part of the oxide semiconductor layer 11o which is not covered with the gate electrode 11g may be exposed to a reductive plasma or a plasma including a doping element (e.g., argon plasma). Thereby, the resistance decreases in the vicinity of the surface of the exposed part of the oxide semiconductor layer 11o, and that region becomes a low-resistance region 11ob.

The portion 11oa of the oxide semiconductor layer 11o which is masked with the gate electrode 11g remains as the first semiconductor region. The methods and conditions for the resistance reduction treatment are disclosed in, for example, Japanese Laid-Open Patent Publication No. 2008-40343. The entire disclosure of Japanese Laid-Open Patent Publication No. 2008-40343 is incorporated by reference in this specification.

Step1-6

Then, an upper insulating layer 15 is formed so as to cover the gate electrode 11g and the oxide semiconductor layer 11o. The upper insulating layer 15 can be realized by a single layer or a multilayer structure of inorganic insulating layers, such as silicon oxide film, silicon nitride film, silicon oxynitride film, silicon nitroxide film, etc. The thickness of the inorganic insulating layer may be not less than 100 nm and not more than 500 nm. Preferably, the upper insulating layer 11 is formed using an insulating film which can deoxidize an oxide semiconductor such as silicon nitride film because the specific resistance of a region of the oxide semiconductor layer 11o which is in contact with the upper insulating layer 15 (herein, the low-resistance region 11ob) can be maintained low. Herein, as the upper insulating layer 15, for example, a SiNx layer (thickness: 300 nm) is formed by CVD.

Thereafter, openings 15a, 15b are formed in the upper insulating layer 15 by, for example, dry etching so as to reach the oxide semiconductor layer 11o.

Step1-7

Then, a source electrode 11s, a drain electrode 11d and a source lines SL are formed on the upper insulating layer 15. Herein, an electrically-conductive film for the source (thickness: for example, not less than 50 nm and not more than 500 nm) is formed on the upper insulating layer 15 and in the openings 15a, 15b, and patterning of the electrically-conductive film for the source is performed, whereby the source electrode 11s, the drain electrode 11d and the source line SL are formed. The patterning can be realized by dry etching or wet etching. In this way, the pixel TF-T 11 can be formed.

As the electrically-conductive film for the source, for example, an element selected from aluminum (Al), chromium (Cr), copper (Cu), tantalum (Ta), titanium (Ti), molybdenum (Mo) and tungsten (W), an alloy film which includes these elements as constituents, or the like, can be used. For example, the electrically-conductive film for the source may have a three-layer structure of titanium film/aluminum film/titanium film, a three-layer structure of molybdenum film/aluminum film/molybdenum film, or the like. The electrically-conductive film for the source is not limited to the three-layer structure but may have a single-layer or two-layer structure or a multilayer structure consisting of four or more layers. Herein, a multilayer film is used which includes a Ti film (thickness: 15-70 nm) as the lower layer and a Cu film (thickness: 200-400 nm) as the upper layer.

Step1-8

Then, an interlayer insulating layer IL is formed so as to cover the pixel TFT 11 and the source line SL. Herein, as the interlayer insulating layer IL, an inorganic insulating layer 16 (thickness: for example, not less than 100 nm and not more than 400 nm) and an organic insulating layer 17 (thickness: for example, 1-3 μm, more preferably 2-3 μm) are formed in this order. The material of the inorganic insulating layer 16 may be the same as that described as an example of the material of the upper insulating layer 15. Herein, as the inorganic insulating layer 16, a SiNx layer (thickness: for example, 200 rim) is formed by CVD. The organic insulating layer 17 may be an organic insulating film which contains a photosensitive resin material. Thereafter, patterning of the organic insulating layer 17 is performed, whereby the opening 17a is formed.

Step1-9

Then, a lower transparent electrode 13 is formed which is to be the common electrode CE.

Firstly, a first transparent electrically-conductive film (thickness: 20-300 nm) is formed on the interlayer insulating layer 16 and in the opening 17a. Herein, for example, an indium-zinc oxide film is formed by sputtering as the first transparent electrically-conductive film. As the material of the first transparent electrode film, a metal oxide such as indium-tin oxide (ITO), indium-zinc oxide, ZnO, or the like, can be used. Thereafter, for example, patterning of the first transparent electrically-conductive film is performed by wet etching. Thereby, the lower transparent electrode 13 is formed. In this example, the lower transparent electrode 13 is provided across an approximate entirety of the display region. Note that, however, the lower transparent electrode 13 has an opening 13a in a region where a pixel contact hole is to be formed. In this example, a part of the first transparent electrically-conductive film which is present inside the opening 13a is removed. Alternatively, a shield layer may be formed using the first transparent electrically-conductive film so as to cover part or the entirety of peripheral circuits.

Step1-10

Then, a dielectric layer (thickness: 50-500 nm) 18 is formed on the interlayer insulating layer IL and the lower transparent electrode 13 and in the opening 17a. The material of the dielectric layer 18 may be the same as that described as an example of the material of the inorganic insulating layer 16. Herein, as the dielectric layer 18, a SiN film is formed by, for example, CVD.

Thereafter, etching of the dielectric layer 18 and the inorganic insulating layer 16 (a part of the inorganic insulating layer 16 which is present inside the opening 17a) is performed, whereby an opening 18a is formed so as to reach a part of the second low-resistance region R2 of the oxide semiconductor layer 11o. The opening 18a may be arranged so as to at least partially overlap the opening 17a when viewed in the substrate-normal direction. Thereby, a pixel contact hole is formed which consists of the opening 17a of the organic insulating layer 17 and the opening 18a of the dielectric layer 18.

Step1-11

Then, a second transparent electrically-conductive film (thickness: 20-300 nm) is formed on the dielectric layer 18 and in the pixel contact hole. Thereafter, patterning of the second transparent electrically-conductive film is performed, whereby an upper transparent electrode 12, which functions as the pixel electrode PE, is formed on the dielectric layer 18. In the upper transparent electrode 12, at least one slit (or notch) 12a is formed for each pixel.

The material of the second transparent electrically-conductive film may be the same as that described as an example of the material of the first transparent electrically-conductive film. The second transparent electrically-conductive film may be a single-layer film or may be a multilayer film. Herein, an indium-zinc oxide film is formed by, for example, sputtering. A part of the upper transparent electrode 12 may be arranged so as to overlap the lower transparent electrode 13 with the dielectric layer 18 interposed therebetween such that storage capacitance is formed. Thereafter, an alignment film is formed so as to cover the pixel electrode PE and the dielectric layer 18. In this way, the active matrix substrate 10 is manufactured.

### Embodiment 2

An active matrix substrate 10A included in a liquid crystal display device of the present embodiment is described with reference to FIG. 11 and FIG. 12. FIG. 11 is a plan view illustrating pixel regions PIX of the active matrix substrate 10A. FIG. 12 is a cross-sectional view taken along line XII-XII′ of FIG. 11. Hereinafter, the differences of the active matrix substrate 10A from the active matrix substrate 10 of Embodiment 1 are mainly described.

As shown in FIG. 11, in the present embodiment, when viewed in the substrate-normal direction, the non-overlapping portion LP2 of the light shielding line LsL is present on the drain electrode 11d side, rather than the source electrode 11s side, relative to the gate line GL. More specifically, the non-overlapping portion LP2 is present between the gate line GL and the drain electrode 11d.

As shown in FIG. 11 and FIG. 12, the light shielding line LsL includes a portion which overlaps a part of the second low-resistance region R2 of the oxide semiconductor layer 11o when viewed in the substrate-normal direction. Further, in the present embodiment, when viewed in the substrate-normal direction, the light shielding line LsL does not overlap the openings 21a of the black matrix 21. That is, the entirety of the light shielding line LsL overlaps the black matrix 21.

In the active matrix substrate 10 of Embodiment 1, edges of the light shielding line LsL are exposed inside the openings 21a of the black matrix 21 and, therefore, there is a probability that the display quality will deteriorate due to stray light which is attributed to reflection and scattering at tapered portions of the edges. Further, since a part of the light shielding line LsL is present in the openings 21a, there is a probability that the aperture ratio will decrease.

In comparison, in the active matrix substrate 10A of the present embodiment, the entirety of the light shielding line LsL overlaps the black matrix 21 when viewed in the substrate-normal direction. Therefore, the edges (tapered portions) of the light shielding line LsL are shielded by the black matrix 21 from light and, thus, deterioration of the display quality due to stray light which is attributed to reflection and scattering at the tapered portions can be prevented. Although FIG. 11 illustrates a configuration where the entirety of the light shielding line LsL overlaps the black matrix 21, substantially the same effects can be achieved so long as an “approximate entirety” of the light shielding line LsL overlaps the black matrix 21. In the specification of the present application, the phrase “an approximate entirety of the light shielding line LsL overlaps the black matrix 21” specifically means that, when viewed in the substrate-normal direction, the proportion of the area of a region of the light shielding line LsL overlapping the black matrix 21 to the total area of the light shielding line LsL is not less than 90%.

In the active matrix substrate 10A of the present embodiment, the light shielding line LsL includes a portion which overlaps a part of the second low-resistance region R2 of the oxide semiconductor layer 11o. Therefore, capacitor is formed in a region where the light shielding line LsL and the second low-resistance region R2 overlap each other (the region sc1 enclosed by a double-dot chain line in FIG. 11 and FIG. 12), and that capacitor can function as the storage capacitor of the pixel. That is, the capacitance value of the storage capacitor of the pixel can be increased. Thus, the influence of noise or other factors which are attributed to the parasitic capacitor of the pixel can be decreased, and occurrence of display failures such as shadowing can be suppressed so that the display quality can be improved.

### Embodiment 3

An active matrix substrate 10B included in a liquid crystal display device of the present embodiment is described with reference to FIG. 13 and FIG. 14. FIG. 13 is a plan view illustrating pixel regions PIX of the active matrix substrate 10B. FIG. 14 is a cross-sectional view taken along line XIV-XIV′ of FIG. 13.

As shown in FIG. 13, when viewed in the substrate-normal direction, the non-overlapping portion LP2 of the light shielding line LsL included in the active matrix substrate 10B of the present embodiment is present on the drain electrode 11d side, rather than the source electrode 11s side, relative to the gate line GL as is the non-overlapping portion LP2 of Embodiment 2. Further, when viewed in the substrate-normal direction, the light shielding line LsL does not overlap the openings 21a of the black matrix 21, but the entirety of the light shielding line LsL overlaps the black matrix 21.

As shown in FIG. 13 and FIG. 14, when viewed in the substrate-normal direction, the light shielding line LsL of the active matrix substrate 10B includes a portion which overlaps a part of the second low-resistance region R2 of the oxide semiconductor layer 11o and a part of the drain electrode 11d.

As previously described, in the active matrix substrate 10B of the present embodiment, the entirety of the light shielding line LaL overlaps the black matrix 21 when viewed in the substrate-normal direction. Therefore, the edges (tapered portions) of the light shielding line LsL are shielded by the black matrix 21 from light and, thus, deterioration of the display quality due to stray light which is attributed to reflection and scattering at the tapered portions can be prevented. Although FIG. 13 illustrates a configuration where the entirety of the light shielding line LsL overlaps the black matrix 21, substantially the same effects can be achieved so long as an approximate entirety of the light shielding line LsL (specifically, 90% or more of the light shielding line LsL) overlaps the black matrix 21.

In the active matrix substrate 10B of the present embodiment, the light shielding line LsL includes portions which overlap the second low-resistance region R2 of the oxide semiconductor layer 11o and the drain electrode 11d and, therefore, capacitor is formed in a region where the light shielding line LsL overlaps the second low-resistance region R2 and a region where the light shielding line LsL overlaps the drain electrode 11d. FIG. 15 shows a region sc1 where the light shielding line LsL overlaps the second low-resistance region R2 and a region sc2 where the light shielding line LaL overlaps the drain electrode 11d. In FIG. 15, for the sake of clarity, the former region sc1 is hatched with lines sloping down to the right and the latter region sc2 is hatched with lines sloping down to the left, while the other regions are not hatched. The capacitor formed in these regions sc1 and sc2 can function as the storage capacitor of the pixel and, therefore, the capacitance value of the storage capacitor of the pixel can be increased. Thus, the influence of noise or other factors which are attributed to the parasitic capacitor of the pixel can be decreased, and the display quality can be improved. In the present embodiment, the light shielding line LsL overlaps not only the second low-resistance region R2 but also the drain electrode 11d (not only the region sc1 but also the region sc2 is present) and, thus, the capacitance value of the storage capacitor can be further increased as compared with Embodiment 2.

### Embodiment 4

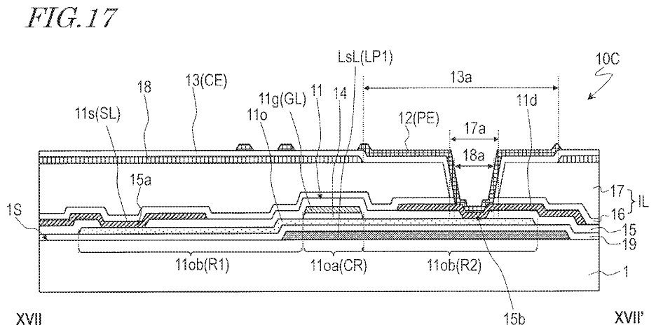

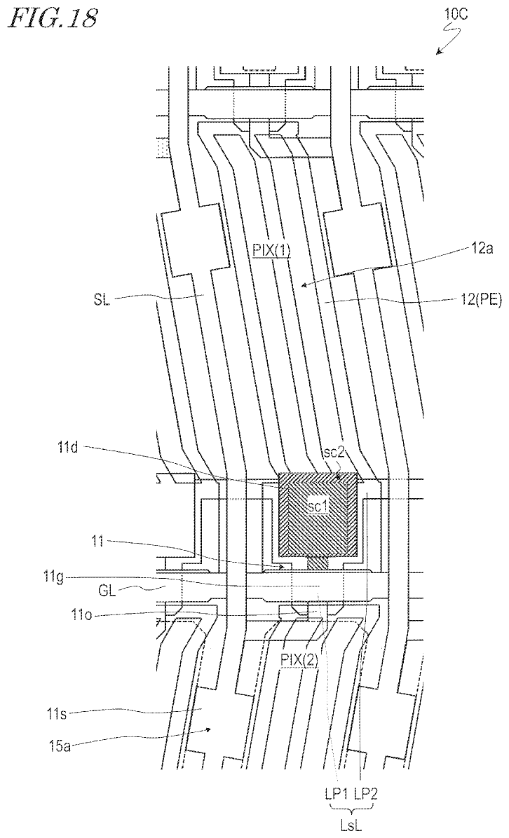

An active matrix substrate 10C included in a liquid crystal display device of the present embodiment is described with reference to FIG. 16 and FIG. 17. FIG. 16 is a plan view illustrating pixel regions PIX of the active matrix substrate 10C. FIG. 17 is a cross-sectional view taken along line XVII-XVII′ of FIG. 16.

As shown in FIG. 16, when viewed in the substrate-normal direction, the non-overlapping portion LP2 of the light shielding line LsL included in the active matrix substrate 10C of the present embodiment is present on the drain electrode 11d side, rather than the source electrode 11s side, relative to the gate line GL as is the non-overlapping portion LP2 of Embodiment 2. Further, when viewed in the substrate-normal direction, the light shielding line LsL does not overlap the openings 21a of the black matrix 21, but the entirety of the light shielding line LsL overlaps the black matrix 21.

As shown in FIG. 16 and FIG. 17, when viewed in the substrate-normal direction, the light shielding line LsL of the active matrix substrate 10C includes a portion which overlaps the entirety of the second low-resistance region R2 of the oxide semiconductor layer 11o and the entirety of the drain electrode 11d.

As previously described, in the active matrix substrate 10C of the present embodiment, the entirety of the light shielding line LsL overlaps the black matrix 21 when viewed in the substrate-normal direction. Therefore, the edges (tapered portions) of the light shielding line LsL are shielded by the black matrix 21 from light and, thus, deterioration of the display quality due to stray light which is attributed to reflection and scattering at the tapered portions can be prevented. Although FIG. 16 illustrates a configuration where the entirety of the light shielding line LsL overlaps the black matrix 21, substantially the same effects can be achieved so long as an approximate entirety of the light shielding line LsL (specifically, 90% or more of the light shielding line LsL) overlaps the black matrix 21.

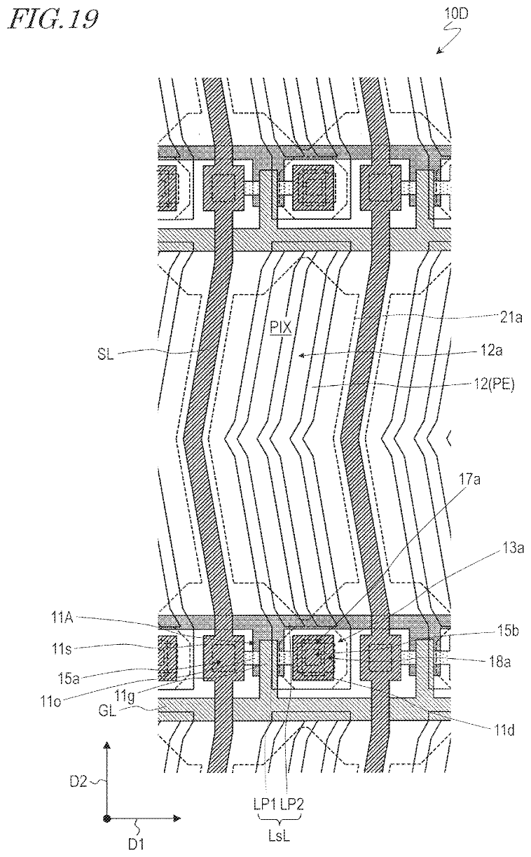

In the active matrix substrate 10C of the present embodiment, the light shielding line LsL includes portions which overlap the second low-resistance region R2 of the oxide semiconductor layer 11o and the drain electrode 11d and, therefore, capacitor is formed in a region where the light shielding line LsL overlaps the second low-resistance region R2 and a region where the light shielding line LsL overlaps the drain electrode 11d. FIG. 18 shows a region sc1 where the light shielding line LsL overlaps the second low-resistance region R2 and a region sc2 where the light shielding line LsL overlaps the drain electrode 11d. In FIG. 18, for the sake of clarity, the former region sc1 is hatched with lines sloping down to the right and the latter region sc2 is hatched with lines sloping down to the left, while the other regions are not hatched. The capacitor formed in these regions sc1 and sc2 can function as the storage capacitor of the pixel and, therefore, the capacitance value of the storage capacitor of the pixel can be increased. Thus, the influence of noise or other factors which are attributed to the parasitic capacitor of the pixel can be decreased, and the display quality can be improved. In the present embodiment, the light shielding line LsL overlaps the entirety of the second low-resistance region R2 and the entirety of the drain electrode 11d and, thus, the capacitance value of the storage capacitor can be further increased as compared with Embodiment 3.

Although FIG. 16 illustrates a configuration where the light shielding line LsL overlaps the entirety of the second low-resistance region R2 and the entirety of the drain electrode 11d, substantially the same effects can be achieved so long as the light shielding line LsL overlaps an “approximate entirety” of the second low-resistance region R2 and an “approximate entirety” of the drain electrode 11d. In the specification of the present application, the phrase “the light shielding line LsL overlaps an approximate entirety of the second low-resistance region R2” specifically means that, when viewed in the substrate-normal direction, the proportion of the area of a region of the second low-resistance region R2 overlapping the light shielding line LsL to the total area of the second low-resistance region R2 is not less than 90%. Also, the phrase “the light shielding line LsL overlaps an approximate entirety of the drain electrode 11d” specifically means that, when viewed in the substrate-normal direction, the proportion of the area of a region of the drain electrode 11d overlapping the light shielding line LsL to the total area of the drain electrode 11d is not less than 90%.

[Capacitor Formed by Light Shielding Line]

From the viewpoint of decreasing the influence of noise or other factors which are attributed to the parasitic capacitor of the pixel, the capacitance value of the capacitor formed in a region where the light shielding line LsL overlaps the second low-resistance region R2 of the oxide semiconductor layer 11o and/or the drain electrode 11d (i.e., additional storage capacitor) is preferably 5% or more, more preferably 15% or more, of the capacitance value of the storage capacitor that the pixel region PIX inherently has (the capacitor formed in a region where the pixel electrode PE overlaps the common electrode CE). A trial calculation was carried out on the example illustrated in Embodiment 4. The capacitance value of the additional storage capacitor was 19% of the capacitance value of the inherent storage capacitor.

[Proportion of Non-Overlapping Portion in Light Shielding Line]

In the light shielding line LsL, the proportion of the non-overlapping portion LP2 (the proportion of the non-overlapping portion LP2 relative to the total area of the light shielding line LsL when viewed in the substrate-normal direction) is not particularly limited but is typically not less than 50%. A trial calculation was carried out on the example illustrated in Embodiment 2. The proportion of the non-overlapping portion LP2 in the light shielding line LaL was about 72%.

### Embodiment 5

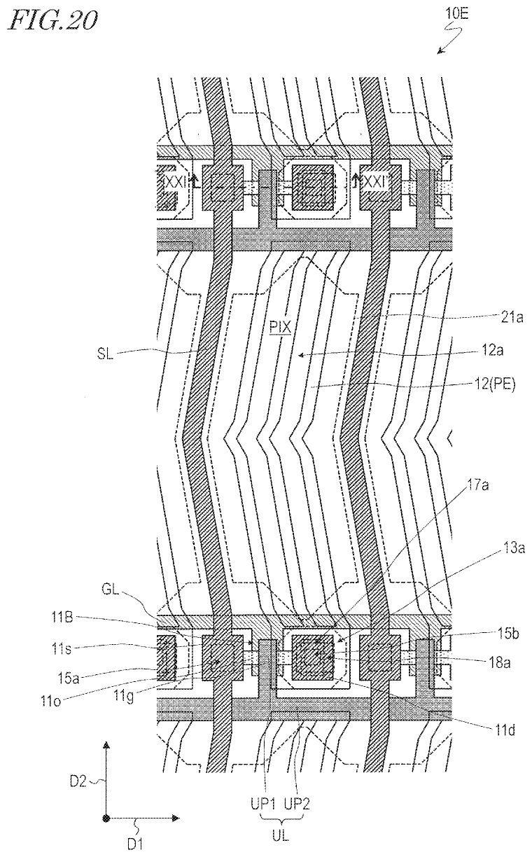

An active matrix substrate 10D included in a liquid crystal display device of the present embodiment is described with reference to FIG. 19. FIG. 19 is a plan view illustrating pixel regions PIX of the active matrix substrate 10D.

As shown in FIG. 19, a pixel TFT 11A of the active matrix substrate 10D is arranged in a corresponding one of the pixel regions PIX such that the channel length direction is identical with the first direction D1 (recumbent-TFT configuration). Herein, a part of the source line SL functions as the source electrode 11s. When viewed in the substrate-normal direction, the gate line GL includes a main portion extending in the first direction D1 and a projection protruding in the second direction D2 from the main portion. The projection functions as the gate electrode 11g. The oxide semiconductor layer 11o extends from above the source line SL so as to traverse the projection of the gate line GL.

Also in the present embodiment, the active matrix substrate 10D includes the light shielding line LsL that includes the channel shielding portion LP1 and the non-overlapping portion LP2 and, therefore, at least the same effects as those of Embodiment 1 can be achieved. Further, since an approximate entirety of the light shielding line LsL overlaps the black matrix 21 (i.e., the light shielding line LsL does not substantially overlap the openings 21a of the black matrix 21), deterioration of the display quality due to stray light which is attributed to reflection and scattering at the edges (tapered portions) of the light shielding line LsL can be prevented as in Embodiment 2.

### Embodiment 6

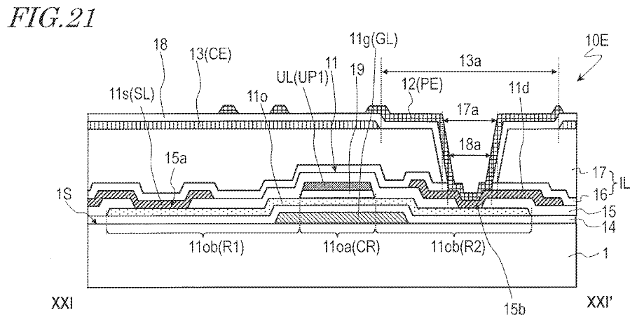

An active matrix substrate 10E included in a liquid crystal display device of the present embodiment is described with reference to FIG. 20 and FIG. 21. FIG. 20 is a plan view illustrating pixel regions PIX of the active matrix substrate 10E. FIG. 21 is a cross-sectional view taken along line XXI-XXI′ of FIG. 20.

As shown in FIG. 20 and FIG. 21, in the present embodiment, a pixel TFT 11B included in the active matrix substrate 10E has a bottom gate configuration. The gate electrode 11g of the TFT 11B is provided under the oxide semiconductor layer 11o with the gate insulating layer 14 interposed therebetween.

The active matrix substrate 10E includes an upper line UL which is provided above the oxide semiconductor layer 11o instead of the light shielding line LsL of Embodiments 1 to 5. The upper line UL is provided with a predetermined potential.

The upper line UL includes a channel overlapping portion UP1 which overlaps the channel region CR of the oxide semiconductor layer 11o when viewed in the substrate-normal direction. The channel overlapping portion UP1 overlaps the channel region CR with the lower insulating layer 19 interposed therebetween, while the lower insulating layer 19 is provided above a part of the oxide semiconductor layer 11o. The upper line UL also includes a non-overlapping portion UP2 which includes a portion extending in the first direction D1 and which does not overlap the gate line GL when viewed in the substrate-normal direction. Thus, the upper line UL does not overlap the gate line GL except inside and in the vicinity of the channel region CR. Also, the upper line UL does not overlap a region in which the gate line GL and the source line SL intersect each other.

When viewed in the substrate-normal direction, the upper line UL does not overlap the openings 21a of the black matrix 21. That is, the entirety of the upper line UL overlaps the black matrix 21.

The upper line UL may be made of an electrically-conductive material which has a light shielding property or may be made of a transparent electrically-conductive material.

As previously described, in the present embodiment, the active matrix substrate 10E includes the upper line UL that includes the channel overlapping portion UP1 and the upper line UL is provided with a predetermined potential (i.e., supplied with a signal from an external device). Therefore, it is possible to control the signal potential on the non-control side of the pixel TFT 11B (in other words, the electric field environment opposite to the gate electrode 11g relative to the oxide semiconductor layer 11o) and stabilize the TFT characteristics. For example, the OFF state in holding the pixel potential (the display signal voltage applied to the pixel electrode PE) can be made more stable (the off-leak current can be reduced).

The non-overlapping portion UP2, which is the other part of the upper line UL than the channel overlapping portion UP1, does not overlap the gate line GL and, therefore, dulling of the scan signal and occurrence of luminance unevenness which are attributed to the increase in load of the gate line GL are prevented.

In the present embodiment, the entirety of the upper line UL overlaps the black matrix 21 when viewed in the substrate-normal direction. Therefore, the edges (tapered portions) of the upper line UL are shielded by the black matrix 21 from light and, thus, deterioration of the display quality due to stray light which is attributed to reflection and scattering at the tapered portions can be prevented. Although FIG. 20 illustrates a configuration where the entirety of the upper line UL overlaps the black matrix 21, substantially the same effects can be achieved so long as an “approximate entirety” of the upper line UL overlaps the black matrix 21. In the specification of the present application, the phrase “an approximate entirety of the upper line UL overlaps the black matrix 21” specifically means that, when viewed in the substrate-normal direction, the proportion of the area of a region of the upper line UL overlapping the black matrix 21 to the total area of the upper line UL is not less than 90%.

[Signal Input to Upper Line]

Although the potential applied to the upper line UL is not particularly limited, it is preferred from the viewpoint of stabilizing the TFT characteristics that the potential applied to the upper line UL is a fixed potential. Specifically, for example, the low-level potential of the gate signal, the GND (ground potential), and a potential between these potentials can be used as the fixed potential.

[Regarding Oxide Semiconductor]

The oxide semiconductor included in the oxide semiconductor layer 11o may be an amorphous oxide semiconductor or may be a crystalline oxide semiconductor which includes a crystalline portion. Examples of the crystalline oxide semiconductor include a polycrystalline oxide semiconductor, a microcrystalline oxide semiconductor, and a crystalline oxide semiconductor in which the c-axis is oriented generally perpendicular to the layer surface.

The oxide semiconductor layer 11o may have a multilayer structure consisting of two or more layers. When the oxide semiconductor layer 11o has a multilayer structure, the oxide semiconductor layer 11o may include an amorphous oxide semiconductor layer and a crystalline oxide semiconductor layer. Alternatively, the oxide semiconductor layer 11o may include a plurality of crystalline oxide semiconductor layers which have different crystalline structures. Still alternatively, the oxide semiconductor layer 11o may include a plurality of amorphous oxide semiconductor layers.

The materials, structures and film formation methods of the amorphous oxide semiconductor and the respective aforementioned crystalline oxide semiconductors, and the configuration of the oxide semiconductor layer which has a multilayer structure, are disclosed in, for example, Japanese Laid-Open Patent Publication No. 2014-007399. The entire disclosure of Japanese Laid-Open Patent Publication No. 2014-007399 is incorporated by reference in this specification.

The oxide semiconductor layer 11o may include, for example, at least one metal element among In, Ga and Zn. In the present embodiment, the oxide semiconductor layer 11o includes, for example, an In—Ga—Zn—O based semiconductor (e.g., indium gallium zinc oxide). Here, the In—Ga—Zn—O based semiconductor is a ternary oxide including In (indium), Ga (gallium) and Zn (zinc). The proportion (composition ratio) of In, Ga and Zn is not particularly limited but includes, for example, In:Ga:Zn=2:2:1, In:Ga:Zn=1:1:1, and In:Ga:Zn=1:1:2. The oxide semiconductor layer 11o which has such a composition can be formed by an oxide semiconductor film which includes an In—Ga—Zn—O based semiconductor.

The In—Ga—Zn—O based semiconductor may be amorphous or may be crystalline. As the crystalline In—Ga—Zn—O based semiconductor, a crystalline In—Ga—Zn—O based semiconductor in which the c-axis is oriented generally perpendicular to the layer surface is preferred.

The crystalline structure of the crystalline In—Ga—Zn—O based semiconductor is disclosed in, for example, aforementioned Japanese Laid-Open Patent Publication No. 2014-007399, Japanese Laid-Open Patent Publication No. 2012-134475, and Japanese Laid-Open Patent Publication No. 2014-209727. The entire disclosures of Japanese Laid-Open Patent Publication No. 2012-134475 and Japanese Laid-Open Patent Publication No. 2014-209727 are incorporated by reference in this specification. A TFT which includes an In—Ga—Zn—O based semiconductor layer has high mobility (20 times or more as compared with an a-Si TFT) and low current leakage (less than 1/100 as compared with an a-Si TFT), and is therefore suitably used as a driver TFT (e.g., a TFT included in a driving circuit provided around the display region including a plurality of pixels on the same substrate as the display region) and a pixel TFT (a TFT provided in a pixel).

The oxide semiconductor layer 11o may contain a different oxide semiconductor instead of the In—Ga—Zn—O based semiconductor. For example, the oxide semiconductor layer 11o may contain an In—Sn—Zn—O based semiconductor (e.g., In₂O₃—SnO—ZnO; InSnZnO). In—Sn—Zn—O based semiconductor is a ternary oxide including In (indium), Sn (tin) and Zn (zinc). Alternatively, the oxide semiconductor layer 11o may contain an In—Al—Zn—O based semiconductor, an In—Al—Sn—Zn—O based semiconductor, a Zn—O based semiconductor, an In—Zn—C based semiconductor, a Zn—Ti—O based semiconductor, a Cd—Ge—O based semiconductor, a Cd—Pb—O based semiconductor, a CdO (cadmium oxide), a Mg—Zn—O based semiconductor, an In—Ga—Sn—O based semiconductor, an In—Ga—O based semiconductor, a Zr—In—Zn—O based semiconductor, a Hf—In—Zn—O based semiconductor, an Al—Ga—Zn—O based semiconductor, a Ga—Zn—O based semiconductor, an In—Ga—Zn—Sn—O based semiconductor, or the like.

According to an embodiment of the present invention, in a display device which includes oxide semiconductor TFTs, occurrence of luminance unevenness which is attributed to a line provided for improvement: in the TFT characteristics (e.g., a light shielding line which includes a portion shielding the channel region of the TFTs from light) can be suppressed. An embodiment of the present invention is suitably used in, for example, a liquid crystal display device.

The present application claims the benefit of U.S. Provisional Application No. 62/733,248 filed on Sep. 19, 2018, the disclosure of which is hereby incorporated by reference in its entirety.

What is claimed is:

1. A display device comprising an active matrix substrate and having a plurality of pixel regions, the active matrix substrate including
a substrate which has a major surface,
a pixel TFT supported on a major surface side of the substrate and arranged so as to correspond to respective one of the plurality of pixel regions,
a gate line extending in a first direction that supplies a gate signal to the pixel TFT, and
a source line extending in a second direction that supplies a source signal to the pixel TFT, the second direction intersecting to the first direction,
wherein the pixel TFT is a top gate configuration TFT that includes an oxide semiconductor layer which includes a channel region and a gate electrode which is electrically coupled with the gate line and which is provided on the oxide semiconductor layer with a gate insulating layer interposed therebetween,
the active matrix substrate further includes a light shielding line which is provided between the substrate and the oxide semiconductor layer and which is made of an electrically-conductive material that has a light shielding property, the light shielding line being provided with a predetermined potential, and
the light shielding line includes a channel shielding portion which shields the channel region of the oxide semiconductor layer from light and a non-overlapping portion which includes a portion extending in the first direction and which does not overlap the gate line when viewed in a direction normal to the major surface of the substrate.

2. The display device of claim 1, wherein the predetermined potential provided to the light shielding line is a fixed potential.

3. The display device of claim 1, wherein the non-overlapping portion of the light shielding line which includes the channel shielding portion that shields from light the channel region of the pixel TFT corresponding to one of the plurality of pixel regions is present outside that pixel region.

4. The display device of claim 1 further comprising a black matrix, wherein when viewed in a direction normal to the major surface of the substrate, an approximate entirety of the light shielding line overlaps the black matrix.

5. The display device of claim 1, wherein
the pixel TFT further includes a source electrode and a drain electrode which are electrically coupled with the oxide semiconductor layer,
the source electrode is connected with the source line, and
when viewed in a direction normal to the major surface of the substrate, the non-overlapping portion of the light shielding line is present on the drain electrode side relative to the gate line.

6. The display device of claim 5, wherein when viewed in a direction normal to the major surface of the substrate, the non-overlapping portion of the light shielding line is present between the gate line and the drain electrode.

7. The display device of claim 6, wherein
the oxide semiconductor layer further includes a first low-resistance region which is present on the source electrode side of the channel region and which has a lower specific resistance than the channel region and a second low-resistance region which is present on the drain electrode side of the channel region and which has a lower specific resistance than the channel region, and
when viewed in a direction normal to the major surface of the substrate, the light shielding line includes a portion which overlaps a part of the second low-resistance region of the oxide semiconductor layer.

8. The display device of claim 5, wherein
the oxide semiconductor layer further includes a first low-resistance region which is present on the source electrode side of the channel region and which has a lower specific resistance than the channel region and a second low-resistance region which is present on the drain electrode side of the channel region and which has a lower specific resistance than the channel region, and
when viewed in a direction normal to the major surface of the substrate, the light shielding line includes a portion which overlaps a part of the second low-resistance region of the oxide semiconductor layer and a part of the drain electrode.

9. The display device of claim 5, wherein
the oxide semiconductor layer further includes a first low-resistance region which is present on the source electrode side of the channel region and which has a lower specific resistance than the channel region and a second low-resistance region which is present on the drain electrode side of the channel region and which has a lower specific resistance than the channel region, and
when viewed in a direction normal to the major surface of the substrate, the light shielding line includes a portion which overlaps an approximate entirety of the second low-resistance region of the oxide semiconductor layer and an approximate entirety of the drain electrode.

10. The display device of claim 1, wherein the light shielding line does not overlap a region in which the gate line and the source line intersect each other.

11. A display device comprising an active matrix substrate and having a plurality of pixel regions, the active matrix substrate including
a substrate which has a major surface,
a pixel TFT supported on a major surface side of the substrate and arranged so as to correspond to respective one of the plurality of pixel regions,
a gate line extending in a first direction that supplies a gate signal to the pixel TFT, and
a source line extending in a second direction that supplies a source signal to the pixel TFT, the second direction intersecting to the first direction,
wherein the pixel TFT is a bottom gate configuration TFT that includes an oxide semiconductor layer which includes a channel region and a gate electrode which is electrically coupled with the gate line and which is provided under the oxide semiconductor layer with a gate insulating layer interposed therebetween,
the active matrix substrate further includes an upper line provided above the oxide semiconductor layer, the upper line being provided with a predetermined potential, and
the upper line includes a channel overlapping portion which overlaps the channel region of the oxide semiconductor layer when viewed in a direction normal to the major surface of the substrate and a non-overlapping portion which includes a portion extending in the first direction and which does not overlap the gate line when viewed in a direction normal to the major surface of the substrate.

12. The display device of claim 1, wherein the oxide semiconductor layer contains an In—Ga—Zn—O based semiconductor.

13. The display device of claim 12, wherein the In—Ga—Zn—O based semiconductor includes a crystalline portion.

14. The display device of claim 1, further comprising:
a counter substrate arranged so as to oppose the active matrix substrate; and
a liquid crystal layer provided between the active matrix substrate and the counter substrate.
